(19) United States
(12) Patent Application Publication
(10) Pub. No.: US 2024/0405014 A1
(43) Pub. Date: Dec. 5, 2024

(54) SEMICONDUCTOR DEVICE

(71) Applicant: SAMSUNG ELECTRONICS CO., LTD., Suwon-si (KR)

(72) Inventors: Jongkyu Song, Suwon-si (KR); Jin Heo, Suwon-si (KR); Minho Kim, Suwon-si (KR); Jooyoung Song, Suwon-si (KR); Eunsuk Lee, Suwon-si (KR); Chanhee Jeon, Suwon-si (KR)

(21) Appl. No.: 18/405,843

(22) Filed: Jan. 5, 2024

(30) Foreign Application Priority Data
May 30, 2023 (KR) 10-2023-0069240

(51) Int. Cl. H01L 27/02; H01L 27/06; H01L 29/06; H01L 29/735; H01L 29/78

(52) U.S. Cl. CPC H01L 27/0262; H01L 27/0266; H01L 27/0635; H01L 29/0603; H01L 29/0684; H01L 29/735; H01L 29/78

(57) ABSTRACT

The present disclosure relates to semiconductor devices. An example semiconductor device includes a first well region and a second well region isolated from each other by a first device isolation film; an NPN transistor provided by a first collector region formed in the first well region and including first conductivity-type impurities, and a first emitter region formed in the second well region and including the first conductivity-type impurities; a PNP transistor provided by a second emitter region formed in the first well region and including second conductivity-type impurities different from the first conductivity-type, and a second collector region formed in the second well region and including the second conductivity-type impurities; and an NMOS transistor including a source region and a drain region formed in the second well region and including the first conductivity-type impurities, and a gate structure disposed between the source region and the drain region.

### CROSS-REFERENCE TO RELATED APPLICATION

This application claims benefit of priority to Korean Patent Application No. 10-2023-0069240 filed on May 30, 2023, in the Korean Intellectual Property Office, the disclosure of which is incorporated herein by reference in its entirety.

### BACKGROUND

A semiconductor device may include a plurality of semiconductor elements, and a portion of the plurality of semiconductor elements may include a receiver circuit and a transmitter circuit for transmitting signals to and receiving signals from other external semiconductor devices. The receiver circuit and the transmitter circuit may be connected to pads for transmitting and receiving signals. To protect semiconductor elements from electrostatic discharge (ESD) which may flow from the outside of the semiconductor device through a pad, a receiver circuit and a transmitter circuit may be connected to an ESD protection circuit. To effectively protect semiconductor elements, it may be necessary to implement an ESD protection circuit operating at an appropriate trigger voltage.

### SUMMARY

The present disclosure relates to semiconductor devices, including a semiconductor device that includes an ESD protection circuit effectively protecting internal semiconductor elements from ESD by reducing a difference between a breakdown voltage and a trigger voltage.

In some implementations, a semiconductor device includes a first well region formed in a substrate and doped with first conductivity-type impurities; a second well region formed in the substrate and doped with second conductivity-type impurities; a first collector region disposed in the first well region and doped with the first conductivity-type impurities; a first emitter region disposed in the second well region and doped with the first conductivity-type impurities; a second emitter region disposed in the first well region, doped with the second conductivity-type impurities, and connected to the first collector region by a first wiring pattern; a second collector region disposed in the second well region, doped with the second conductivity-type impurities, and connected to the first emitter region by a second wiring pattern; a source region and a drain region disposed in the second well region, doped with the first conductivity-type impurities, and electrically isolated from the first well region; and a gate structure disposed on the second well region between the source region and the drain region in a first direction parallel to an upper surface of the substrate and electrically connected to the source region or the drain region.

In some implementations, a semiconductor device includes a first pad configured to input and output a signal; a second pad supplied with a reference voltage; an NPN transistor including a first collector connected to the first pad, a first emitter connected to the second pad, and a first base; a PNP transistor including a second emitter connected to the first pad, a second collector connected to the second pad and the first base, and a second base connected to the first collector; an NMOS transistor including a drain connected to the first collector, a source connected to the second pad, and a gate connected to the source or the drain; and a first diode having an anode connected to the drain, and a cathode connected to the first collector and the second base.

In some implementations, a semiconductor device includes a first well region and a second well region isolated from each other by a first device isolation film; an NPN transistor provided by a first collector region formed in the first well region and doped with first conductivity-type impurities, and a first emitter region formed in the second well region and doped with first conductivity-type impurities; a PNP transistor provided by a second emitter region formed in the first well region and doped with second conductivity-type impurities different from the first conductivity-type, and a second collector region formed in the second well region and doped with the second conductivity-type impurities; and an NMOS transistor including a source region and a drain region formed in the second well region and doped with the first conductivity-type impurities, and a gate structure disposed between the source region and the drain region, wherein the source region and the drain region are isolated from each other by the first emitter region and a second device isolation film.

### BRIEF DESCRIPTION OF THE DRAWINGS

The above and other aspects, features, and advantages in the example implementations will be more clearly understood from the following detailed description, taken in combination with the accompanying drawings.

FIG. 1 is a block diagram illustrating an example of a semiconductor device.

FIGS. 2 and 3 are diagrams illustrating an example of an ESD protection circuit included in a semiconductor device.

FIG. 4 is a graph indicating an example operation of an ESD protection circuit illustrated in FIGS. 2 and 3.

FIGS. 5 and 6 are diagrams illustrating another example of an ESD protection circuit included in a semiconductor device.

FIGS. 7 and 8 are graphs illustrating example operations of an ESD protection circuit illustrated in FIGS. 5 and 6.

FIGS. 9 and 10 are diagrams illustrating another example of an ESD protection circuit included in a semiconductor device.

FIGS. 11 and 12 are diagrams illustrating another example of an ESD protection circuit included in a semiconductor device.

FIGS. 13 and 14 are diagrams illustrating another example of an ESD protection circuit included in a semiconductor device.

FIGS. 15 and 16 are diagrams illustrating another example of an ESD protection circuit included in a semiconductor device.

FIGS. 17 to 20 are diagrams illustrating another example of an ESD protection circuit included in a semiconductor device.

FIGS. 21 and 22 are diagrams illustrating another example of an ESD protection circuit included in a semiconductor device.

FIGS. 23 and 24 are diagrams illustrating another example of an ESD protection circuit included in a semiconductor device.

FIGS. 25 and 26 are diagrams illustrating another example of an ESD protection circuit included in a semiconductor device.

FIGS. 27 and 28 are diagrams illustrating another example of an ESD protection circuit included in a semiconductor device.

### DETAILED DESCRIPTION

Hereinafter, example implementations will be described as follows with reference to the accompanying drawings.

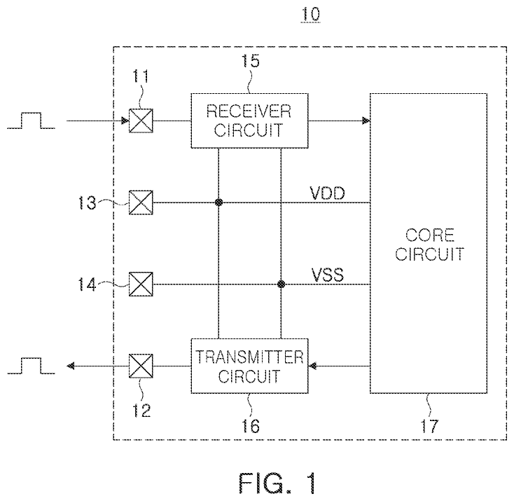

FIG. 1 is a block diagram illustrating an example of a semiconductor device.

Referring to FIG. 1, a semiconductor device 10 includes signal pads 11 and 12, power pads 13 and 14, a receiver circuit 15, a transmitter circuit 16, and a core circuit 17. The semiconductor device 10 may exchange signals with other external semiconductor devices through the signal pads 11 and 12. For example, the receiver circuit 15 may receive an external input signal through the input pad 11 of the signal pads 11 and 12, and the transmitter circuit 16 may transmit an external output signal through the output pad 12 of the signal pads 11 and 12.

Each of the receiver circuit 15, the transmitter circuit 16 and the core circuit 17 may include a plurality of semiconductor elements. The receiver circuit 15 may include a receiver, and the transmitter circuit 16 may include a driving circuit. The core circuit 17 may be implemented as a variety of circuits required for the semiconductor device 10 to provide predetermined functions, and may include, for example, a central processing unit (CPU), a graphics processing unit (GPU), an image signal processor (ISP), a neural processing unit (NPU), a modem, and a cache memory.

The receiver circuit 15 may process an external input signal input to the input pad 11 and may transmit the signal to the core circuit 17. The transmitter circuit 16 may generate an external output signal by processing the signal received from the core circuit 17, and may send out the external output signal through the output pad 12. In some implementations, each of the external input signal and the external output signal may be configured as to have a predetermined frequency as illustrated in FIG. 1.

A power voltage VDD and a reference voltage VSS required for each operation of the receiver circuit 15, the transmitter circuit 16, and the core circuit 17 may be input to the power pads 13 and 14. For example, the power voltage VDD may be input to the first power pad 13, and the reference voltage VSS having a level lower than a level of the power voltage VDD may be input to the second power pad 14.

A high voltage due to electrostatic discharge may be applied to at least a portion of pads 11 to 14 of the semiconductor device 10. For example, in an ESD event condition in which a high voltage is applied to at least one of the signal pads 11 and 12 due to electrostatic discharge, a relatively high level of current may flow in the semiconductor element included in the receiver circuit 15 and the transmitter circuit 16, and accordingly, the semiconductor element may be damaged. In some implementations, an ESD event may occur in a circumstance in which a body may be in close proximity to at least one of the floating pads 11-14.

To prevent damages to a semiconductor element which may occur in an ESD event condition as described above, an ESD protection circuit providing a current movement path may be included in the receiver circuit 15 and the transmitter circuit 16. In some implementations, the ESD protection circuit may include an input/output protection circuit including diodes connected to one of the signal pads 11 and 12, and a clamp circuit.

The ESD protection circuit may provide a path through which a current flowing into the semiconductor device 10 flows under an ESD event condition. Ideally, the current flowing into the signal pads 11 and 12 caused by electrostatic discharge around the semiconductor device 10 may flow out to the second power pad 14 by the ESD protection circuit.

For example, the ESD protection circuit may be implemented as a silicon controlled rectifier (SCR) circuit including a PNP transistor and an NPN transistor. The SCR circuit may have a breakdown voltage and a trigger voltage determined according to properties of the PNP transistor and the NPN transistor, and avalanche breakdown may occur at a trigger voltage higher than the breakdown voltage and a current may flow, such that the current caused by ESD may flow to the second power pad 14. However, it may be difficult to effectively protect internal semiconductor elements from ESD due to a difference between the breakdown voltage and the trigger voltage.

In some implementations, an NMOS transistor may be included in an ESD protection circuit. A current due to ESD may flow to the NMOS transistor first, and as the current flows to the NMOS transistor, the PNP transistor and the NPN transistor may operate. Accordingly, by lowering the trigger voltage, the semiconductor elements in the semiconductor device 10 may be effectively protected in a circumstance in which ESD occurs.

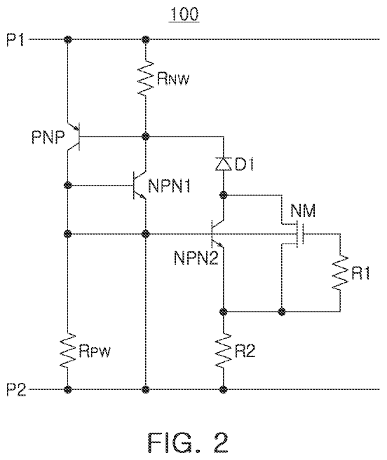

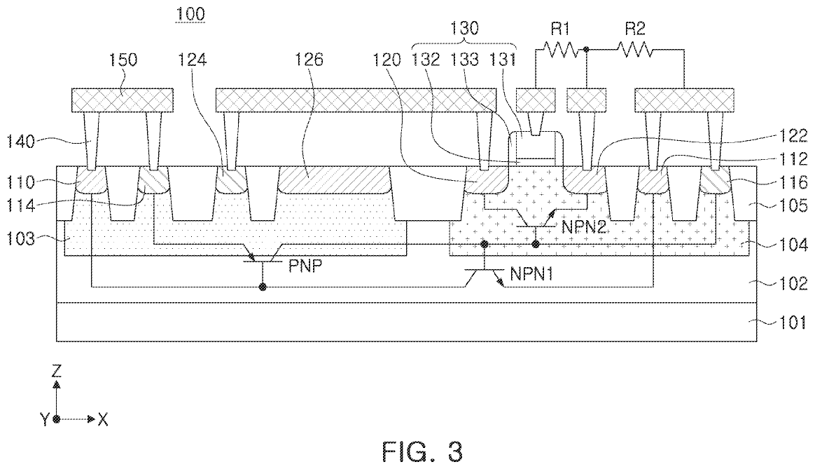

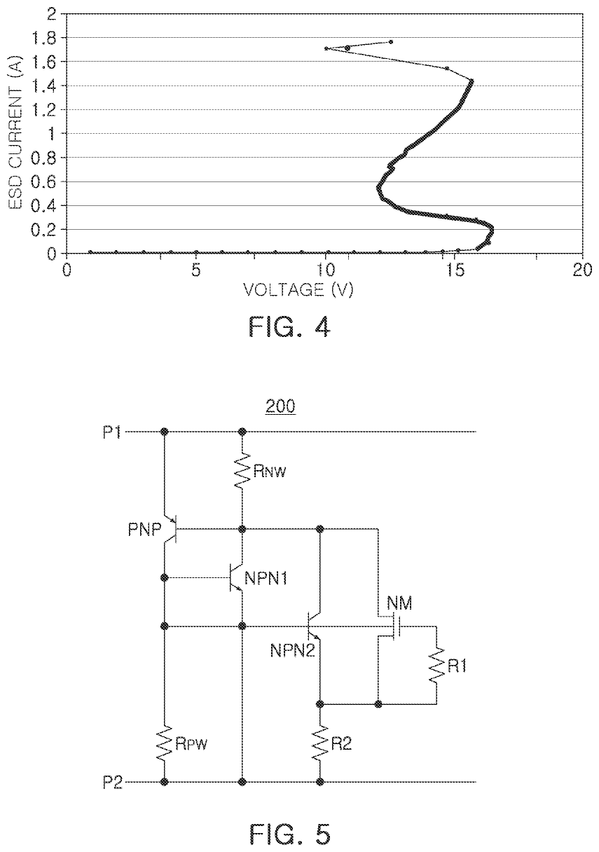

FIGS. 2 and 3 are diagrams illustrating an example of an ESD protection circuit included in a semiconductor device. FIG. 4 is a graph indicating an example operation of an ESD protection circuit illustrated in FIGS. 2 and 3.

Referring to FIG. 2, an ESD protection circuit 100 includes a PNP transistor PNP, a first NPN transistor NPN1, a second NPN transistor NPN2, an NMOS transistor NM, and a first diode D1. An emitter of PNP transistor PNP may be connected to the first pad P1 through which signals are input and/or output, and a collector of first NPN transistor NPN1 may be connected to the first pad P1 through the first well resistor R_{NW}. A collector of the PNP transistor PNP may be connected to the reference pad P2 to which the reference voltage is supplied through the second well resistor R_{PW}, and an emitter of the first NPN transistor NPN1 may be connected to the second pad P2. In some implementations, the reference voltage may be a ground voltage.

A base of the PNP transistor PNP may be connected to the collector of the first NPN transistor NPN1, and a base of the first NPN transistor NPN1 may be connected to the collector of the PNP transistor PNP. A collector of the second NPN transistor NPN2 may be connected to an anode of the first diode D1 and a drain of the NMOS transistor NM, and a cathode of the first diode D1 may be connected to the collector of the first NPN transistor NPN1. A base of the second NPN transistor NPN2 may be connected to the emitter of the first NPN transistor NPN1 and the collector of the PNP transistor PNP, and an emitter of second NPN transistor NPN2 may be connected to a source of the NMOS transistor NM.

In the example implementation illustrated in FIG. 2, the NMOS transistor NM may have a GGNMOS structure. For example, a gate of the NMOS transistor NM may be connected to a source through the first external resistor R1. The source of NMOS transistor NM may be connected to second pad P2 through the second external resistor R2. A resistance value of the first external resistor R1 may be 60 kΩ or more. For example, a resistance value of the second external resistor R2 may also be 60 kΩ or more.

FIG. 3 may be an example implementation of the ESD protection circuit 100 in FIG. 2. Referring to FIG. 3, a deep-well region 102 may be formed on the substrate 101, and a first well region 103 and a second well region 104 may be formed on the deep-well region 102. For example, the deep-well region 102 and the first well region 103 may be doped with the same first conductivity-type impurities, and the second well region 104 may be doped with second conductivity-type impurities different from the first conductivity-type. The first conductivity-type impurities may be N-type impurities, and the second conductivity-type impurities may be P-type impurities. A first well resistor R_{NW} may be provided by a resistive element of the first well region 103, and a second well resistor R_{PW} may be provided by a resistive element of the second well region 104.

In each of the first well region 103 and the second well region 104, a plurality of active regions and a device isolation film 105 isolating the plurality of active regions from each other may be formed. A portion of the plurality of active regions may provide a PNP transistor PNP, a first NPN transistor NPN1, a second NPN transistor NPN2, and a NMOS transistor NM.

First, a first collector region 110 providing a collector of the first NPN transistor NPN1 may be formed in the first well region 103, and a first emitter region 112 providing an emitter of the first NPN transistor NPN1 may be formed in the second well region 104. Each of the first collector region 110 and the first emitter region 112 may be doped with first conductivity-type impurities, and may have a concentration of impurities higher than that of the first well region 103. A base of the first NPN transistor NPN1 may be provided by the second well region 104.

A second emitter region 114 providing an emitter of the PNP transistor PNP may be formed in the first well region 103, and a second collector region 116 providing a collector of the PNP transistor PNP may be formed in the second well region 104. Each of the second emitter region 114 and the second collector region 116 may be doped with second conductivity-type impurities, and may have a concentration of impurities higher than that of the second well region 104. The base of the PNP transistor PNP may be provided by the first well region 103.

The NMOS transistor NM may include a drain region 120, a source region 122, and a gate structure 130 disposed therebetween in a first direction (X-axis direction) parallel to an upper surface of the substrate 101. The gate structure 130 may include a gate electrode layer 131, a gate insulating layer 132 and a gate spacer 133. Each of the drain region 120 and the source region 122 may be formed in the second well region 104, and may be doped with second conductivity-type impurities to have a concentration higher than that of the second well region 104.

The second NPN transistor NPN2 may be provided by the drain region 120 and the source region 122 and the second well region 104. For example, the drain region 120 may provide a collector for the second NPN transistor NPN2, the source region 122 may provide an emitter for the second NPN transistor NPN2, and the second well region 104 may provide a base for the second NPN transistor NPN2.

The drain region 120 may be connected to the first active region 124 formed in the first well region 103 by a third wiring pattern. The first active region 124 may be doped with second conductivity-type impurities and may provide an anode of the first diode D1, and the drain region 120 may be provided as a cathode of the first diode D1. A second active region 126 may be formed between the first active region 124 and the second well region 104 in the first direction. The second active region 126 may be formed in the first well region 103, may be doped with first conductivity-type impurities, and may have an area larger than that of the first active region 124.

Referring to FIG. 3, a plurality of contacts 140 may be connected to at least a portion of the plurality of active regions, and the plurality of contacts 140 may be connected to the plurality of wiring patterns 150. For example, the first collector region 110 may be connected to the second emitter region 114 by a first wiring pattern, and the first emitter region 112 may be connected to the second collector region 116 by a second wiring pattern. The first wiring pattern may be connected to the first pad in which the signal is input/output, and the second wiring pattern may be connected to the second pad to which the reference voltage is supplied. The gate structure 130 may be connected to the source region 122 through the first external resistor R1, and the source region 122 may be connected to a second wiring pattern into which a reference voltage is input through the second external resistor R2.

Hereinafter, operations of the ESD protection circuit 100 illustrated in FIGS. 2 and 3 will be described with reference to FIG. 4.

Referring to the graph in FIG. 4, an ESD current generated due to an ESD event is illustrated. An ESD current may flow when the voltage applied to first pad P1 increases above a predetermined level due to an ESD event, and a voltage at which the ESD current rapidly increases may be defined as a trigger voltage.

When an ESD event occurs, an ESD current may first flow from a first wiring pattern connected to the first pad P1 to the first diode D1 and the NMOS transistor NM. As the ESD current flows to the first diode D1 and the NMOS transistor NM, a voltage of the second well region 104 may increase, and a base voltage of the first NPN transistor NPN1 may increase. As the base voltage increases, the first NPN transistor NPN1 may be swiftly turned on and the ESD protection circuit 100 may start a SCR operation.

In some implementations, the ESD protection circuit 100 may start an SCR operation and may reduce a difference between a trigger voltage and a breakdown voltage through which ESD current may flow. In the example implementation illustrated in FIG. 4, the difference between the breakdown voltage and the trigger voltage may be within 3V. Accordingly, together with the ESD protection circuit 100, the semiconductor elements included in a semiconductor device may be effectively protected.

The trigger voltage at which the ESD protection circuit 100 starts the SCR operation may vary depending on the design of the ESD protection circuit 100. For example, the trigger voltage may be changed by removing the first diode D1 from the ESD protection circuit 100 or changing a threshold voltage of the NMOS transistor NM by changing a thickness of the gate insulating layer 132 included in the gate structure 130.

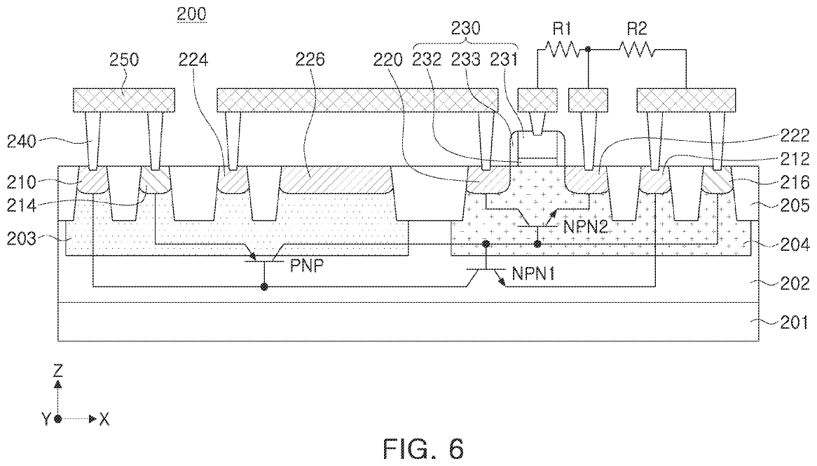

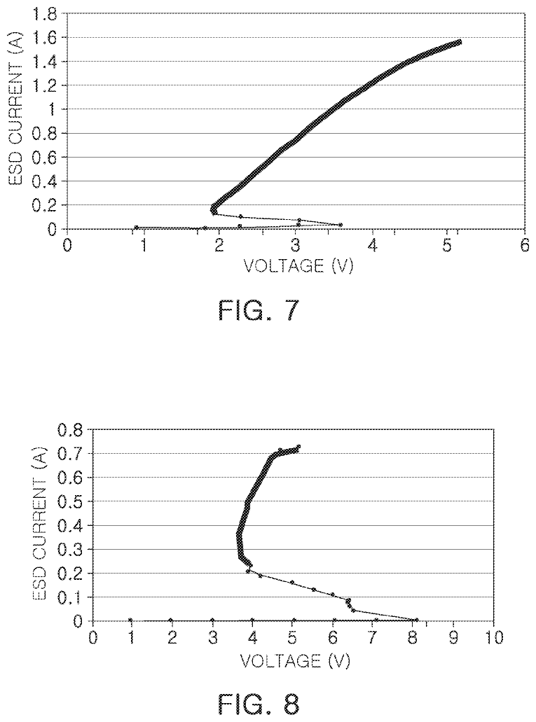

FIGS. 5 and 6 are diagrams illustrating another example of an ESD protection circuit included in a semiconductor device. FIGS. 7 and 8 are graphs illustrating example operation of an ESD protection circuit illustrated in FIGS. 5 and 6.

Referring to FIG. 5, the ESD protection circuit 200 includes a PNP transistor PNP, a first NPN transistor NPN1, a second NPN transistor NPN2, an NMOS transistor NM, a first external resistor R1, and a second external resistor R2. As compared to the ESD protection circuit 100 described in the example implementation with reference to FIG. 2, the first diode D1 may not be present, and accordingly, a drain of the NMOS transistor NM may be connected to a collector of the second NPN transistor NPN2. Also, a collector of the first NPN transistor NPN1 may be connected to a collector of the second NPN transistor NPN2.

FIG. 6 may be an example implementation of the ESD protection circuit 200 in FIG. 3. Other than the first diode D1, the ESD protection circuit 200 illustrated in FIG. 6 may have a structure similar to that of the ESD protection circuit 100 described in the example implementation with reference to FIG. 3.

Referring to FIG. 6, a deep-well region 202, a first well region 203 and a second well region 204 may be formed on a substrate 201. In each of the first well region 203 and the second well region 204, a plurality of active regions and a device isolation film 205 isolating the plurality of active regions may be formed. In the first well region 203, a first collector region 210 providing a collector of the first NPN transistor NPN1 and a second emitter region 214 providing an emitter of the PNP transistor PNP may be formed. In the example implementation illustrated in FIG. 3, the first active region 124 may be doped with second conductivity-type impurities, whereas in the example implementation illustrated in FIG. 6, a first active region 224 doped with first conductivity-type impurities may be formed in the same position. The first active region 224 may be connected to the drain region 220 by a third wiring pattern. A second active region 226 having an area larger than that of the first active region 224 may be formed between the first active region 224 and the second well region 204.

In the second well region 204, a first emitter region 212 providing an emitter of the first NPN transistor NPN1 and a second collector region 216 providing a collector of the PNP transistor PNP may be formed. The NMOS transistor NM may include a drain region 220 and a source region 222 formed in the second well region 204, and a gate structure 230 disposed therebetween. The gate structure 230 may include a gate electrode layer 231, a gate insulating layer 232 and a gate spacer 233.

A plurality of contacts 240 may be connected to at least a portion of the plurality of active regions, and the plurality of contacts 240 may be connected to a plurality of wiring patterns 250. The first collector region 210 may be connected to the second emitter region 214 through a first wiring pattern, and the first emitter region 212 may be connected to the second collector region 216 through a second wiring pattern. The first wiring pattern may be connected to the first pad P1, and the second wiring pattern may be connected to the second pad P2. The gate structure 230 may be connected to the source region 222 through a first external resistor R1, and the source region 222 may be connected to a second wiring pattern through a second external resistor R2.

Hereinafter, operations of the ESD protection circuit 100 illustrated in FIGS. 5 and 6 will be described with reference to FIGS. 7 and 8.

Referring to FIGS. 7 and 8, an ESD current generated due to an ESD event is illustrated. An ESD current may flow when the voltage applied to first pad P1 increases above a predetermined level due to an ESD event, and a voltage at which the ESD current rapidly increases may be defined as a trigger voltage.

When an ESD event occurs, an ESD current may flow from the first wiring pattern connected to the first pad P1 to the NMOS transistor NM. As the ESD current flows to the NMOS transistor NM, a voltage of the second well region 104 may increase, and a base voltage of the first NPN transistor NPN1 may increase. As the base voltage increases, the first NPN transistor NPN1 may be swiftly turned on and the ESD protection circuit 200 may start a SCR operation. As compared to the example implementation described with reference to FIGS. 2 to 4, since the first diode D1 may not be present, the trigger voltage at which the ESD protection circuit 200 starts the SCR operation may be lowered.

Comparing FIG. 7 and FIG. 8, a level of the trigger voltage in the graph illustrated in FIG. 7 may be relatively lower, which may be due to a difference in thicknesses of the gate insulating layers 232 included in the gate structure 230. For example, the thickness of the gate insulating layer 232 included in the ESD protection circuit 200 having ESD current properties as illustrated in FIG. 7 may be smaller than thickness of the gate insulating layer 232 included in the ESD protection circuit 200 having ESD current properties as illustrated in FIG. 8. In other words, the NMOS transistor NM included in the ESD protection circuit 200 having ESD current properties as illustrated in FIG. 7 may have a relatively small threshold voltage as compared to that of the NMOS transistor NM included in the ESD protection circuit 200 having ESD current properties as illustrated in FIG. 8.

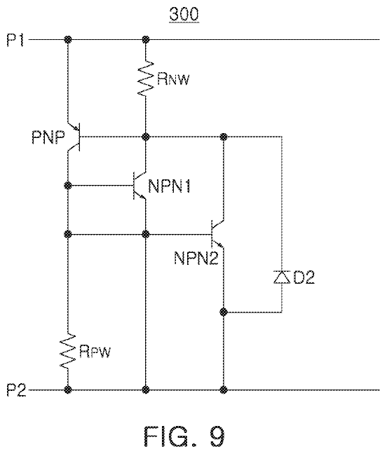

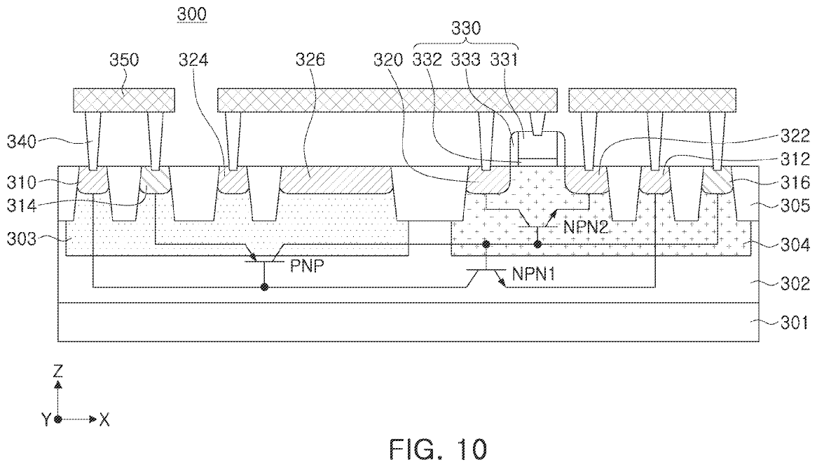

FIGS. 9 and 10 are diagrams illustrating another example of an ESD protection circuit included in a semiconductor device.

Referring to FIG. 9, an ESD protection circuit 300 includes a PNP transistor PNP, a first NPN transistor NPN1, a second NPN transistor NPN2, and a second diode D2. An anode of the second diode D2 may be connected to an emitter of the second NPN transistor NPN2 and the second pad P2, and a cathode may be connected to a collector of the first NPN transistor NPN1 and a collector of the second NPN transistor NPN2.

FIG. 10 may be an example implementation of the ESD protection circuit 300 in FIG. 9. Referring to FIG. 10, a deep-well region 302, a first well region 303 and a second well region 304 may be formed on a substrate 301. In each of the first well region 303 and the second well region 304, a plurality of active regions and a device isolation film 305 isolating the plurality of active regions from each other may be formed. A first collector region 310 providing a collector of the first NPN transistor NPN1 and a second emitter region 314 providing an emitter of the PNP transistor PNP may be formed in the first well region 303.

In the second well region 304, a first emitter region 312 providing an emitter of the first NPN transistor NPN1 and a second collector region 316 providing a collector of the PNP transistor PNP may be formed. In the second well region 304, a drain region 320, a source region 322, and a gate structure 330 disposed therebetween may be formed such that an NMOS transistor may be implemented. The gate structure 330 may include a gate electrode layer 331, a gate insulating layer 332 and a gate spacer 333. In some implementations, an active region doped with P-type impurities may be further formed in the second well region 304, and the active region may be disposed between the first well region 303 and the NMOS transistor. An area of the active region may be larger than that of each of the drain region 320, the source region 322, the first emitter region 312, and the second collector region 316.

A plurality of contacts 340 may be connected to at least a portion of the plurality of active regions, and the plurality of contacts 340 may be connected to a plurality of wiring patterns 350. The first collector region 310 may be connected to the second emitter region 314 by a first wiring pattern, and the first emitter region 312 may be connected to the second collector region 316 by a second wiring pattern. The first wiring pattern may be connected to a first pad P1, and the second wiring pattern may be connected to a second pad P2.

In the example implementation illustrated in FIG. 10, the drain region 320 may be connected to the first active region 324 formed in the first well region 303 through a third wiring pattern, and the first active region 324 may be a region doped with first conductivity-type impurities. Accordingly, differently from the example implementation described above with reference to FIGS. 2 and 3, the first diode D1 may not be included in the ESD protection circuit 300. A second active region 326 having an area larger than that of the first active region 324 may be formed between the first active region 324 and the second well region 304.

A third wiring pattern may connect the drain region 320 to the gate structure 330. As illustrated in FIG. 10, by connecting the drain region 320 to the gate structure 330, the NMOS transistor may operate as a second diode D2. In other words, the second diode D2 may be configured as a MOS diode. Accordingly, the source region 322 may not be connected to the gate structure 330. The source region 322 may be connected to the second pad P2 by a second wiring pattern.

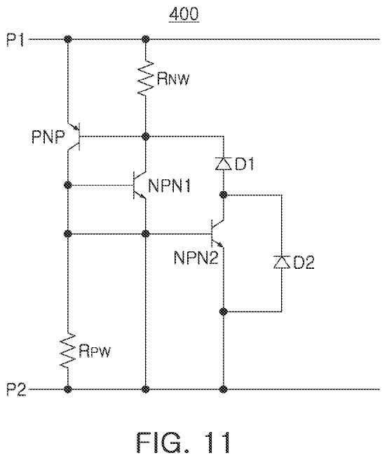

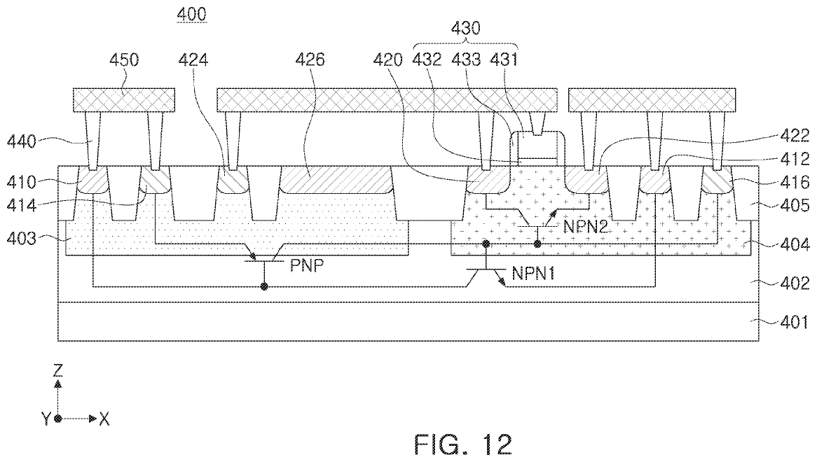

FIGS. 11 and 12 are diagrams illustrating another example of an ESD protection circuit included in a semiconductor device.

Referring first to FIG. 11, an ESD protection circuit 400 includes a PNP transistor PNP, a first NPN transistor NPN1, a second NPN transistor NPN2, a first diode D1, and a second diode D2. An anode of first diode D1 may be connected to a collector of second NPN transistor NPN2, and a cathode of first diode D1 may be connected to a collector of first NPN transistor NPN2. An anode of the second diode D2 may be connected to an emitter and second pad P2 of the second NPN transistor NPN2, and a cathode of the second diode D2 may be connected to an anode of the first diode D1.

FIG. 12 may be an example implementation of the ESD protection circuit 400 in FIG. 11. Referring to FIG. 12, a deep-well region 402, a first well region 403 and a second well region 404 may be formed on a substrate 401. In each of the first well region 403 and the second well region 404, a plurality of active regions and a device isolation film 405 isolating the plurality of active regions from each other may be formed. A first collector region 410 and a second emitter region 414 may be formed in the first well region 403, and a first emitter region 412 and a second collector region 416 may be formed in the second well region 404 such that a PNP transistor PNP and a first NPN transistor NPN1 may be implemented.

In the second well region 404, a drain region 420, a source region 422, and a gate structure 430 disposed therebetween may be formed such that an NMOS transistor may be implemented. The gate structure 430 may include a gate electrode layer 431, a gate insulating layer 432 and a gate spacer 433. In some implementations, an active region doped with P-type impurities may be further formed in the second well region 404, and the active region may be disposed between the first well region 403 and the NMOS transistor. An area of the active region may be larger than that of each of the drain region 420, the source region 422, the first emitter region 412, and the second collector region 416.

A plurality of contacts 440 may be connected to at least a portion of the plurality of active regions, and the plurality of contacts 440 may be connected to a plurality of wiring patterns 450. The first collector region 410 may be connected to the second emitter region 414 by a first wiring pattern, and the first emitter region 412 may be connected to the second collector region 416 by a second wiring pattern. The first wiring pattern may be connected to a first pad P1, and the second wiring pattern may be connected to a second pad P2. A drain region 420 and the gate structure 430 may be connected to the first active region 424 formed in the first well region 403 through a third wiring pattern. Accordingly, the NMOS transistor may be implemented as a MOS diode and may provide a second diode D2. A second active region 426 having an area larger than that of the first active region 424 and doped with first conductivity-type impurities may be formed between the first active region 424 and the second well region 404.

The ESD protection circuit 400 described in the example implementation with reference to FIGS. 11 and 12 may further include a first diode D1 as compared to the ESD protection circuit 300 described in the example implementation with reference to FIGS. 9 and 10. Accordingly, the ESD protection circuit 400 described in the example implementation with reference to FIGS. 11 and 12 may have a relatively higher level of trigger voltage.

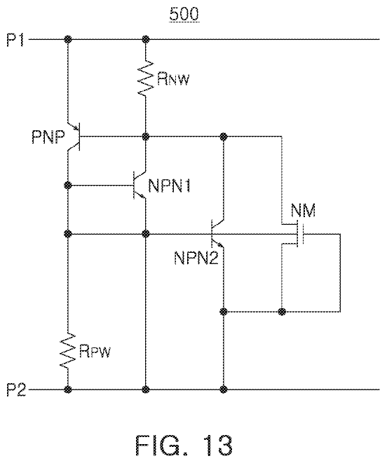

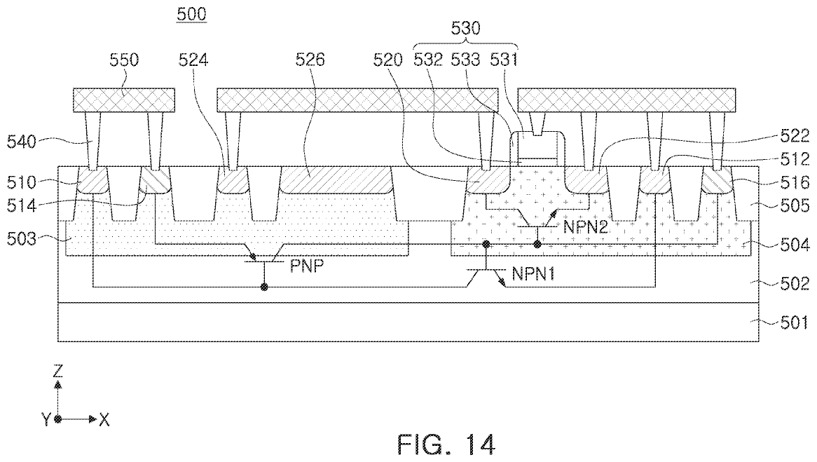

FIGS. 13 and 14 are diagrams illustrating another example of an ESD protection circuit included in a semiconductor device.

Referring to FIG. 13, an ESD protection circuit 500 includes a PNP transistor PNP, a first NPN transistor NPN1, a second NPN transistor NPN2, and an NMOS transistor NM. A gate of NMOS transistor NM may be directly connected to a source without an external resistor, and a source of NMOS transistor NM may be directly connected to a second pad P2 without an external resistor.

In other words, the ESD protection circuit 500 may have a structure in which external resistors R1 and R2 are not provided as compared to the ESD protection circuit 200 described in the example implementation with reference to FIG. 5. Accordingly, the ESD protection circuit 500 may have a relatively high level of trigger voltage as compared to the ESD protection circuit 200 described in the example implementation with reference to FIG. 5. When the trigger voltage is to be lowered in the ESD protection circuit 500 in the example implementation illustrated in FIG. 13, a threshold voltage of the NMOS transistor NM included in the ESD protection circuit 500 may be configured to be relatively low. For example, a trigger voltage of the ESD protection circuit 500 may be lowered by changing a width and/or length of the channel region of the NMOS transistor NM.

FIG. 14 may be an example implementation of the ESD protection circuit 500 in FIG. 12. Referring to FIG. 14, a deep-well region 502, a first well region 503 and a second well region 504 may be formed on a substrate 501. The deep-well region 502 and the first well region 503 may be doped with first conductivity-type impurities, and the second well region 504 may be doped with second conductivity-type impurities.

In each of the first well region 503 and the second well region 504, a plurality of active regions and a device isolation film 505 isolating the plurality of active regions from each other may be formed. A first collector region 510 and a second emitter region 514 may be formed in the first well region 503, and a first emitter region 512 and a second collector region 516 may be formed in the second well region 504 such that a PNP transistor PNP and a first NPN transistor NPN1 may be implemented.

In the second well region 504, a drain region 520, a source region 522, and a gate structure 530 disposed therebetween may be formed such that an NMOS transistor NM may be implemented. The gate structure 530 may include a gate electrode layer 531, a gate insulating layer 532 and a gate spacer 533. A plurality of contacts 540 may be connected to at least a portion of the plurality of active regions, and the plurality of contacts 540 may be connected to the plurality of wiring patterns 550.

The first collector region 510 may be connected to the second emitter region 514 by a first wiring pattern, and the first emitter region 512 may be connected to the second collector region 516 by a second wiring pattern. The first wiring pattern may be connected to a first pad P1, and the second wiring pattern may be connected to a second pad P2. The drain region 520 may be connected to the first active region 524 formed in the first well region 503 through a third wiring pattern. The first active region 524 may be a region doped with first conductivity-type impurities. A second active region 526 having an area larger than that of the first active region 524 may be formed between the first active region 524 and the second well region 504.

The gate structure 530 may be directly connected to the source region 522 through a wiring pattern. A wiring pattern connecting the gate structure 530 and the source region 522 may be a second wiring pattern, and may also be connected to the first emitter region 512 and the second collector region 516.

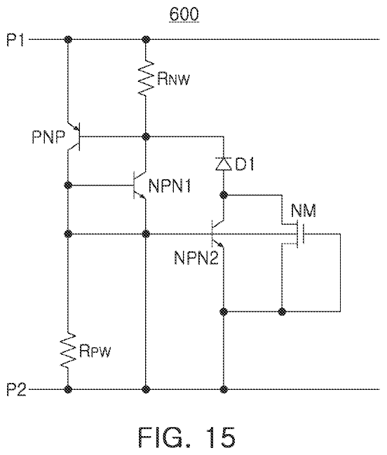

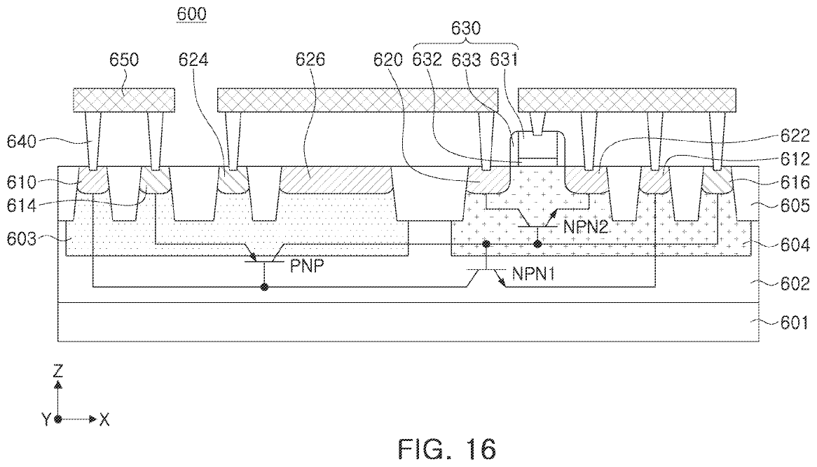

FIGS. 15 and 16 are diagrams illustrating another example of an ESD protection circuit included in a semiconductor device.

Referring to FIG. 15, an ESD protection circuit 600 includes a PNP transistor PNP, a first NPN transistor NPN1, a second NPN transistor NPN2, a first diode D1, and an NMOS transistor NM. Similarly to the example implementation described with reference to FIG. 14, a gate of the NMOS transistor NM may be directly connected without a source and an external resistor, and a source of the NMOS transistor NM may be directly connected to the second pad P2 without an external resistor.

In other words, the ESD protection circuit 600 may have a structure in which a first diode D1 is added as compared to the ESD protection circuit 500 described in the example implementation with reference to FIG. 13. Accordingly, the trigger voltage of the ESD protection circuit 600 may be higher than the trigger voltage of the ESD protection circuit 500 described in the example implementation with reference to FIG. 13.

FIG. 16 may be an example implementation of the ESD protection circuit 600 in FIG. 15. Referring to FIG. 16, a deep-well region 602 and a first well region 603 doped with first conductivity-type impurities, and a second well region 604 doped with second conductivity-type impurities may be formed on a substrate 601. A concentration of impurities in the deep-well region 602 may be lower than those in the first well region 603 and the second well region 604.

In each of the first well region 603 and the second well region 604, a plurality of active regions and a device isolation film 605 isolating the plurality of active regions from each other may be formed. A first collector region 610 and a second emitter region 614 may be formed in the first well region 603, and a first emitter region 612 and a second collector region 616 may be formed in the second well region 604 such that a PNP transistor PNP and a first NPN transistor NPN1 may be formed.

In the second well region 604, a drain region 620, a source region 622, and a gate structure 630 disposed therebetween may be formed such that an NMOS transistor NM may be implemented. The drain region 620 and the source region 622 may provide a second NPN transistor NPN2 together with the second well region 604. A plurality of contacts 640 may be connected to at least a portion of the plurality of active regions, and the plurality of contacts 640 may be connected to a plurality of wiring patterns 650.

The first collector region 610 may be connected to the second emitter region 614 by a first wiring pattern, and the first emitter region 612 may be connected to the second collector region 616 by a second wiring pattern. The first wiring pattern may be connected to a first pad P1, and the second wiring pattern may be connected to a second pad P2. The drain region 620 may be connected to the first active region 624 formed in the first well region 603 through a third wiring pattern. The first active region 624 may be a region doped with second conductivity-type impurities, and may provide an anode of the first diode D1. A second active region 626 having an area larger than that of the first active region 624 and doped with first conductivity-type impurities may be formed between the first active region 624 and the second well region 604.

A gate structure 630 may be directly connected to the source region 622 through a wiring pattern. A wiring pattern connecting the gate structure 630 and the source region 622 may be a second wiring pattern, and may also be connected to the first emitter region 612 and the second collector region 616.

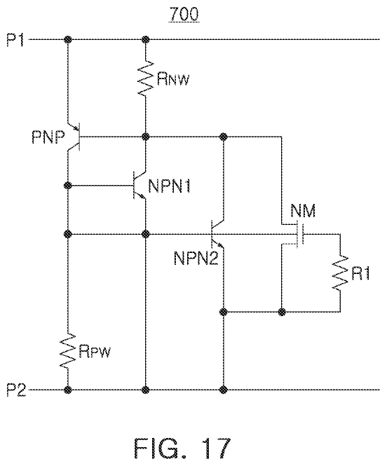

FIGS. 17 to 20 are diagrams illustrating another example of an ESD protection circuit included in a semiconductor device.

Referring to FIG. 17, an ESD protection circuit 700 includes a PNP transistor PNP, a first NPN transistor NPN1, a second NPN transistor NPN2, an NMOS transistor NM, and a first external resistor R1. A first external resistor R1 may be connected between a gate and source of NMOS transistor NM, and a source of NMOS transistor NM may be directly connected to a second pad P2 without an external resistor.

The ESD protection circuit 700 may have a structure in which a first external resistor R1 is added as compared to the ESD protection circuit 500 described in the example implementation with reference to FIG. 13. Accordingly, the ESD protection circuit 700 may have a relatively low level of trigger voltage as compared to the ESD protection circuit 500 described in the example implementation with reference to FIG. 13.

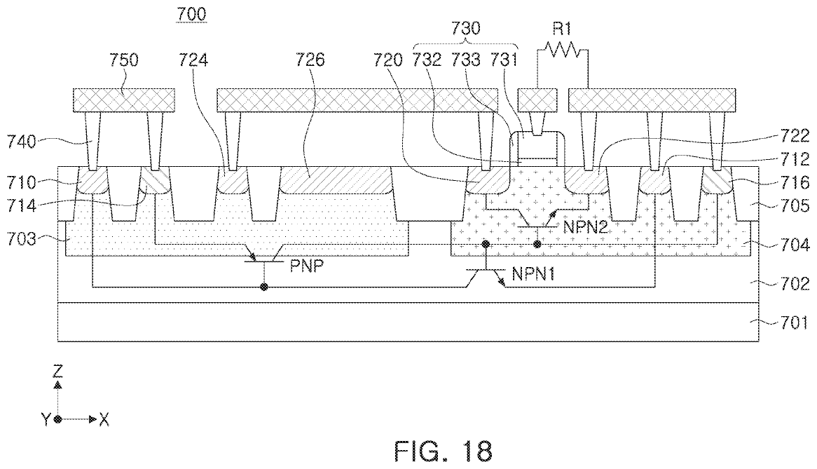

FIGS. 18 to 20 may be an example implementation of the ESD protection circuit 700 illustrated in FIG. 17. Referring first to FIG. 18, a deep-well region 702, a first well region 703 and a second well region 704 may be formed on a substrate 701. The deep-well region 702 and the first well region 703 may be doped with first conductivity-type impurities and the second well region 704 may be doped with second conductivity-type impurities.

In each of the first well region 703 and the second well region 704, a plurality of active regions and a device isolation film 705 isolating the plurality of active regions from each other may be formed. A first collector region 710 and a second emitter region 714 may be formed in the first well region 703, and a first emitter region 712 and a second collector region 716 may be formed in the second well region 704 such that a PNP transistor PNP and a first NPN transistor NPN1 may be implemented.

In the second well region 704, a drain region 720, a source region 722, and a gate structure 730 disposed therebetween may be formed such that an NMOS transistor NM may be implemented. The gate structure 730 may include a gate electrode layer 731, a gate insulating layer 732 and a gate spacer 733. A plurality of contacts 740 may be connected to at least a portion of the plurality of active regions, and the plurality of contacts 740 may be connected to a plurality of wiring patterns 750.

The first collector region 710 may be connected to the second emitter region 714 by a first wiring pattern, and the first emitter region 712 may be connected to the second collector region 716 by a second wiring pattern. The first wiring pattern may be connected to first pad P1, and the second wiring pattern may be connected to second pad P2.

The drain region 720 may be connected to the first active region 724 doped with first conductivity-type impurities through a third wiring pattern. A second active region 726 having an area larger than that of the first active region 724 may be formed between the first active region 724 and the second well region 704. The gate structure 730 may be connected to the source region 722 through a first external resistor R1. The source region 722 may be connected to the first emitter region 712 and the second collector region 716 through a second wiring pattern.

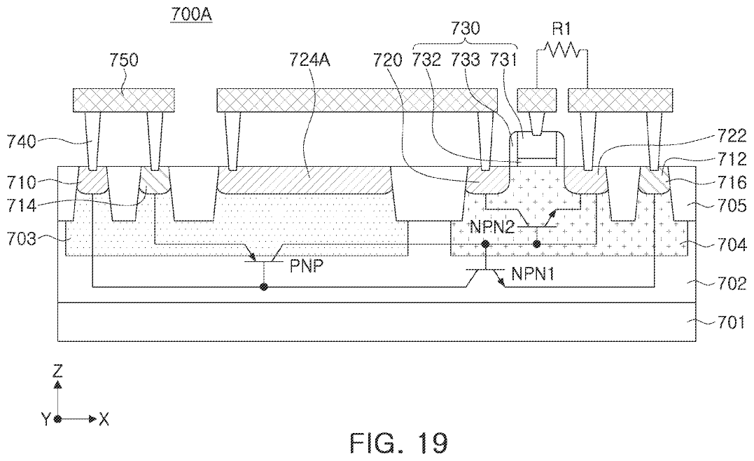

In the ESD protection circuit 700A in the example implementation illustrated in FIG. 19, as compared to the ESD protection circuit 700 in the example implementation illustrated in FIG. 18, the first active region 724A connected to the third wiring pattern may have a different structure. In the example implementation illustrated in FIG. 19, the first active region 724A connected to the third wiring pattern may be formed to be directly adjacent to the device isolation film between the first well region 703 and the second well region 704.

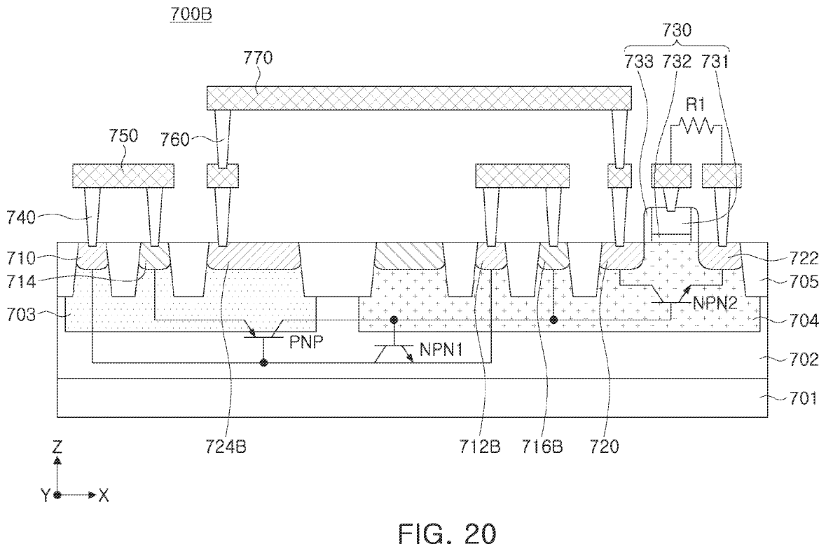

In the ESD protection circuit 700B in the example implementation illustrated in FIG. 20, the arrangement order of elements in the first direction (X-axis direction) may be different from the ESD protection circuits 700 and 700A described with reference to FIGS. 18 and 19. Referring to FIG. 20, a first emitter region 712B and a second collector region 716B may be disposed between a device isolation film between the first well region 703 and the second well region 704 and the NMOS transistor NM. The first emitter region 712B and the second collector region 716B may be connected to second pad P2 through a lower contact 740 and a lower wiring pattern 750.

The first active region 724B formed in the first well region 703 may be connected to the drain region 720 through the lower contact 740, the lower wiring pattern 750, the lower contact 760 and the lower wiring pattern 770. Since the first emitter region 712B and the second collector region 716B are disposed between the NMOS transistor NM and the first well region 703, the first emitter region 712B and the second collector region 716B may be electrically connected to the source region 722 via different wiring patterns disposed in different positions in the second direction (Y-axis direction) and/or the third direction (Z-axis direction). Accordingly, A length of the wiring pattern connecting the first emitter region 712B and the second collector region 716B to the source region 722 may increase as compared to the example implementations described with reference to FIGS. 18 and 19, and the wiring pattern may function similarly to an external resistor disposed between the source region 722 and the second pad P2.

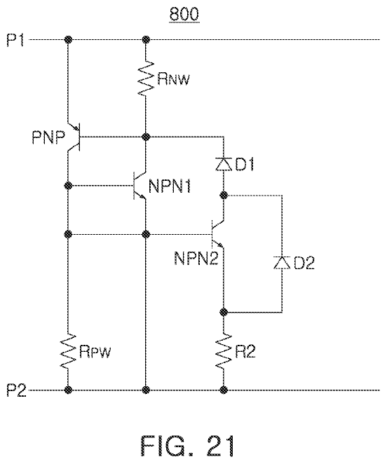

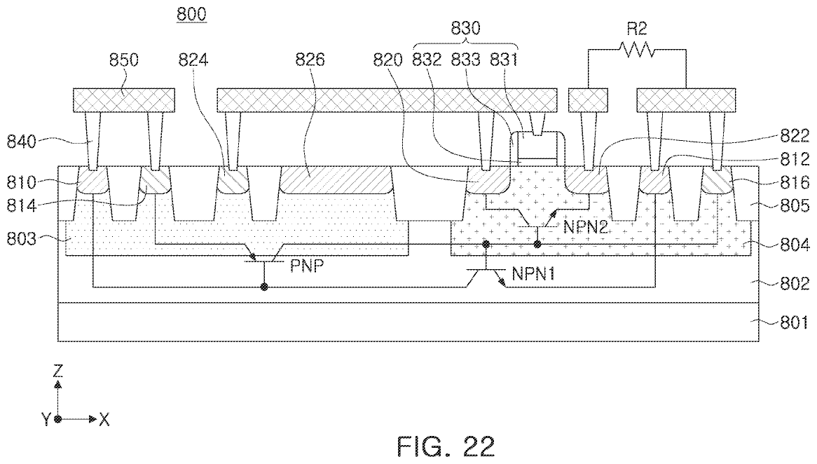

FIGS. 21 and 22 are diagrams illustrating another example of an ESD protection circuit included in a semiconductor device.

Referring to FIG. 21, the ESD protection circuit 800 includes a PNP transistor PNP, a first NPN transistor NPN1, a second NPN transistor NPN2, a first diode D1, a second diode D2, and a second external resistor R2. The ESD protection circuit 800 in the example implementation illustrated in FIG. 21 may have a structure in which a second external resistor R2 is added to the ESD protection circuit 400 described with reference to FIG. 11. Accordingly, the ESD protection circuit 800 may have a relatively higher level of trigger voltage than that of the ESD protection circuit 400 described with reference to FIG. 11.

FIG. 22 may be an example implementation of the ESD protection circuit 400 in FIG. 21. Referring to FIG. 22, a deep-well region 802, a first well region 803 and a second well region 804 may be formed on a substrate 801. In each of the first well region 803 and the second well region 804, a plurality of active regions and a device isolation film 805 isolating the plurality of active regions from each other may be formed. A first collector region 810 and a second emitter region 814 may be formed in the first well region 803, and a first emitter region 812 and a second collector region 816 may be formed in the second well region 804 such that a PNP transistor PNP and a first NPN transistor NPN1 may be implemented.

In the second well region 804, a drain region 820, a source region 822, and a gate structure 830 disposed therebetween may be formed such that an NMOS transistor may be implemented. The gate structure 830 may include a gate electrode layer 831, a gate insulating layer 832 and a gate spacer 833.

A plurality of contacts 840 may be connected to at least a portion of the plurality of active regions, and the plurality of contacts 840 may be connected to a plurality of wiring patterns 850. The first collector region 810 may be connected to the second emitter region 814 by a first wiring pattern, and the first emitter region 812 may be connected to the second collector region 816 by a second wiring pattern. The first wiring pattern may be connected to a first pad P1, and the second wiring pattern may be connected to a second pad P2. The drain region 820 and the gate structure 830 may be connected to the first active region 824 formed in the first well region 803 through a third wiring pattern. Accordingly, the NMOS transistor may be implemented as a MOS diode and may provide a second diode D2. A second active region 826 having an area larger than that of the first active region 824 and doped with first conductivity-type impurities may be formed between the first active region 824 and the second well region 804.

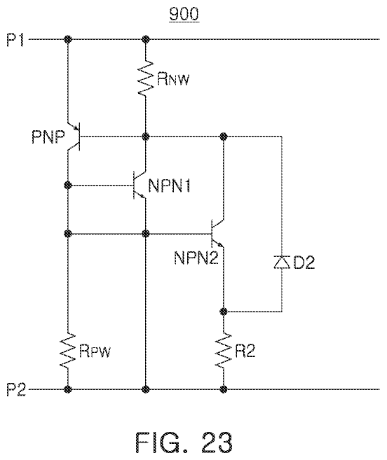

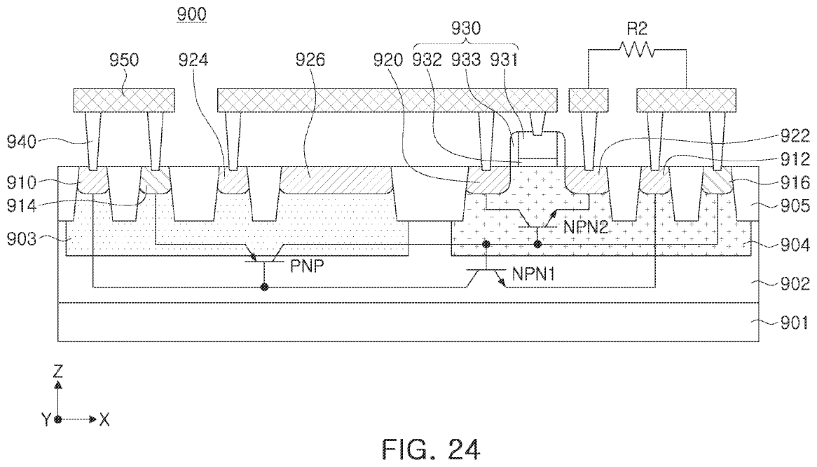

FIGS. 23 and 24 are diagrams illustrating another example of an ESD protection circuit included in a semiconductor device.

Referring to FIG. 23, an ESD protection circuit 900 includes a PNP transistor PNP, a first NPN transistor NPN1, a second NPN transistor NPN2, a second diode D2, and a second external resistor R2. The ESD protection circuit 900 in the example implementation illustrated in FIG. 23 may have a structure in which a second external resistor R2 is added to the ESD protection circuit 300 described with reference to FIG. 9.

FIG. 24 may be an example implementation of the ESD protection circuit 900 in FIG. 23. Referring to FIG. 24, a deep-well region 902, a first well region 903 and a second well region 904 may be formed on a substrate 901. In each of the first well region 903 and the second well region 904, a plurality of active regions and a device isolation film 905 isolating the plurality of active regions from each other may be formed. In the first well region 903, a first collector region 910 providing a collector of the first NPN transistor NPN1 and a second emitter region 914 providing an emitter of the PNP transistor PNP may be formed.

In the second well region 904, a first emitter region 912 providing an emitter of the first NPN transistor NPN1 and a second collector region 916 providing a collector of the PNP transistor PNP may be formed. In the second well region 904, a drain region 920, a source region 922, and a gate structure 930 disposed therebetween may be formed such that an NMOS transistor may be formed.

A plurality of contacts 940 may be connected to at least a portion of the plurality of active regions, and the plurality of contacts 940 may be connected to a plurality of wiring patterns 950. The first collector region 910 may be connected to the second emitter region 914 through a first wiring pattern, and the first emitter region 912 may be connected to the second collector region 916 through a second wiring pattern. The first wiring pattern may be connected to the first pad P1 in which the signal is input/output, and the second wiring pattern may be connected to the second pad P2 in which the reference voltage is input.

In the example implementation illustrated in FIG. 24, the drain region 920 may be connected to the first active region 924 formed in the first well region 903 and the gate structure 930 through a third wiring pattern. Accordingly, the NMOS transistor may operate as the second diode D2. The first active region 924 may be doped with first conductivity-type impurities. The source region 322 may not be connected to the gate structure 330 and may be connected to the second pad P2 by a second wiring pattern. A second active region 926 having an area larger than that of the first active region 924 may be formed between the first active region 924 and the second well region 904.

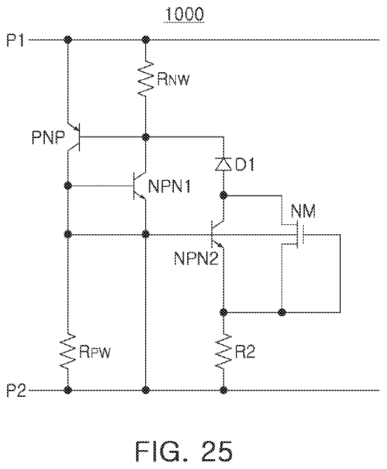

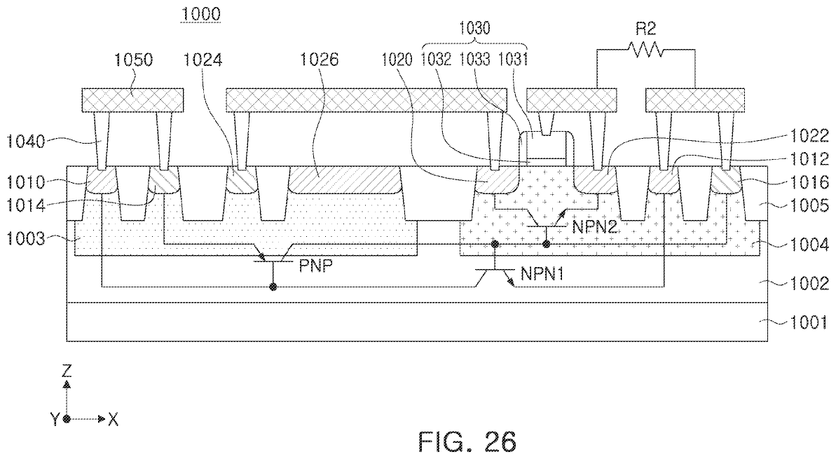

FIGS. 25 and 26 are diagrams illustrating another example of an ESD protection circuit included in a semiconductor device.

Referring to FIG. 25, an ESD protection circuit 1000 includes a PNP transistor PNP, a first NPN transistor NPN1, a second NPN transistor NPN2, a first diode D1, an NMOS transistor NM, and a second external resistor R2. The ESD protection circuit 1000 in the example implementation illustrated in FIG. 23 may have a structure in which the first external resistor R1 is removed from the ESD protection circuit 100 described with reference to FIG. 2. Since the first external resistor R1 is removed, the ESD protection circuit 1000 may have a relatively higher level of trigger voltage than that of the ESD protection circuit 100 described with reference to FIG. 2.

FIG. 26 may be an example implementation of the ESD protection circuit 1000 in FIG. 25. Referring to FIG. 26, a deep-well region 1002, a first well region 1003 and a second well region 1004 may be formed on a substrate 1001. In each of the first well region 1003 and the second well region 1004, a plurality of active regions and a device isolation film 1005 isolating the plurality of active regions may be formed. In the first well region 1003, a first collector region 1010 providing a collector for the first NPN transistor NPN1 and a second emitter region 1014 providing an emitter for the PNP transistor PNP may be formed.

In the second well region 1004, a first emitter region 1012 providing an emitter of the first NPN transistor NPN1 and a second collector region 1016 providing a collector of the PNP transistor PNP may be formed. In the second well region 1004, a drain region 1020, a source region 1022, and a gate structure 1030 disposed therebetween may be formed such that an NMOS transistor NM may be implemented.

A plurality of contacts 1040 may be connected to at least a portion of the plurality of active regions, and the plurality of contacts 1040 may be connected to a plurality of wiring patterns 1050. The first collector region 1010 may be connected to the second emitter region 1014 by a first wiring pattern, and the first emitter region 1012 may be connected to the second collector region 1016 by a second wiring pattern. The first wiring pattern may be connected to the first pad P1 in which the signal is input/output, and the second wiring pattern may be connected to the second pad P2 in which the reference voltage is input.

In the example implementation illustrated in FIG. 26, the drain region 1020 may be connected to the first active region 1024 formed in the first well region 1003 through a third wiring pattern. The first active region 1024 may be doped with second conductivity-type impurities, and may provide an anode of the first diode D1. The source region 1022 may be directly connected to the gate structure 1030 without an external resistor, and the source region 1022 may be connected to a second wiring pattern through a second external resistor R2. A second active region 1026 having an area larger than that of the first active region 1024 may be formed between the first active region 1024 and the second well region 1004.

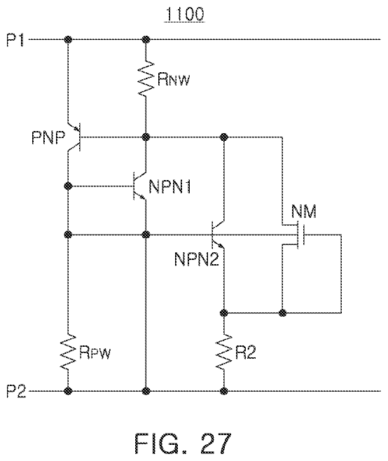

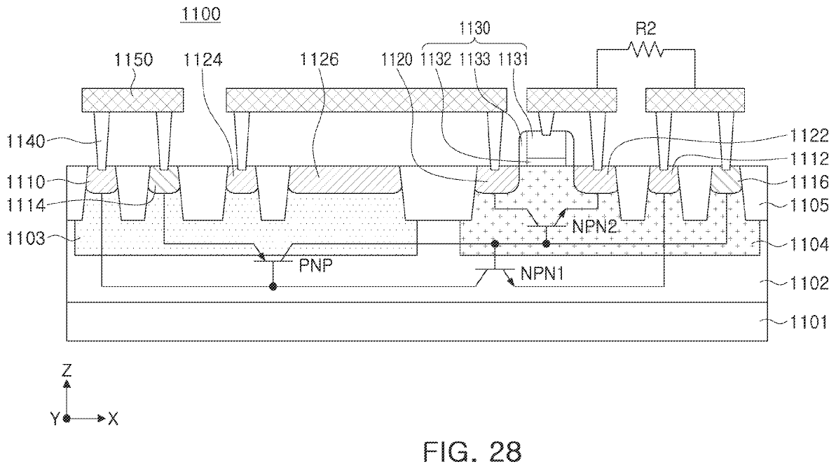

FIGS. 27 and 28 are diagrams illustrating another example of an ESD protection circuit included in a semiconductor device.

Referring to FIG. 27, an ESD protection circuit 1100 includes a PNP transistor PNP, a first NPN transistor NPN1, a second NPN transistor NPN2, an NMOS transistor NM, and a second external resistor R2. The ESD protection circuit 1100 in the example implementation illustrated in FIG. 27 may have a structure in which the first diode D1 is removed from the ESD protection circuit 1000 described with reference to FIG. 25.

FIG. 28 may be an example implementation of the ESD protection circuit 1000 in FIG. 27. Referring to FIG. 28, a deep-well region 1102, a first well region 1103 and a second well region 1104 may be formed on a substrate 1101. In each of the first well region 1103 and the second well region 1104, a plurality of active regions and a device isolation film 1105 isolating the plurality of active regions from each other may be formed. In the first well region 1103, a first collector region 1110 providing a collector of the first NPN transistor NPN1 and a second emitter region 1114 providing an emitter of the PNP transistor PNP may be formed.

In the second well region 1104, a first emitter region 1112 providing an emitter of the first NPN transistor NPN1 and a second collector region 1116 providing a collector of the PNP transistor PNP may be formed. In the second well region 1104, a drain region 1120, a source region 1122, and a gate structure 1130 disposed therebetween may be formed such that an NMOS transistor NM may be implemented.

A plurality of contacts 1140 may be connected to at least a portion of the plurality of active regions, and the plurality of contacts 1140 may be connected to a plurality of wiring patterns 1150. The first collector region 1110 may be connected to the second emitter region 1114 by a first wiring pattern, and the first emitter region 1112 may be connected to the second collector region 1116 by a second wiring pattern. The first wiring pattern may be connected to the first pad P1 in which the signal is input/output, and the second wiring pattern may be connected to the second pad P2 in which the reference voltage is input.

In the example implementation illustrated in FIG. 28, the drain region 1120 may be connected to the first active region 1124 formed in the first well region 1103 through a third wiring pattern. The first active region 1124 may be doped with first conductivity-type impurities, and accordingly, differently from the example implementation illustrated in FIG. 26, a first diode D1 may not be implemented. The source region 1122 may be directly connected to the gate structure 1130 without an external resistor, and the source region 1122 may be connected to a second wiring pattern through a second external resistor R2. A second active region 1126 having an area larger than that of the first active region 1124 may be formed between the first active region 1124 and the second well region 1104.

According to the aforementioned example implementations, the ESD protection circuit further may include an NMOS transistor in addition to the PNP transistor and the NPN transistor, and by implementing the NMOS transistor in various structures of GGNMOS and MOS diode, the trigger voltage of the ESD protection circuit may be configured to fit to a desired target voltage. Also, by reducing a difference between the breakdown voltage and the trigger voltage, semiconductor elements included in the semiconductor device may be effectively protected from ESD.

While this specification contains many specific implementation details, these should not be construed as limitations on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations and even initially be claimed as such, one or more features from a claimed combination can in some cases be excised from the combination, and the claimed combination may be directed to a subcombination or variation of a subcombination.

While the example implementations have been illustrated and described above, it will be configured as apparent to those skilled in the art that modifications and variations may be made without departing from the scope in the example implementation as defined by the appended claims.

What is claimed is:

1. A semiconductor device, comprising:
a first well region formed in a substrate, the first well region including first conductivity-type impurities;
a second well region formed in the substrate, the second well region including second conductivity-type impurities;
a first collector region disposed in the first well region, the first collector region including the first conductivity-type impurities;
a first emitter region disposed in the second well region, the first emitter region including the first conductivity-type impurities;
a second emitter region disposed in the first well region, the second emitter region including the second conductivity-type impurities, and the second emitter region being connected to the first collector region by a first wiring pattern;
a second collector region disposed in the second well region, the second collector region including the second conductivity-type impurities, and the second collector region being connected to the first emitter region by a second wiring pattern;
a source region and a drain region disposed in the second well region, the source region and the drain region including the first conductivity-type impurities, and the source region and the drain region electrically isolated from the first well region; and
a gate structure disposed on the second well region between the source region and the drain region in a first direction, the first direction being parallel to an upper surface of the substrate, and the gate structure being electrically connected to the source region or the drain region.

2. The semiconductor device of claim 1, wherein the first well region and the second well region are isolated from each other by a device isolation film in the first direction.

3. The semiconductor device of claim 1, further comprising:
a first external resistor connected between the gate structure and the source region.

4. The semiconductor device of claim 3, further comprising:
a second external resistor connected between the source region and the second wiring pattern.

5. The semiconductor device of claim 1, further comprising:
A first active region disposed in the first well region, the first active region including the first conductivity-type impurities or the second conductivity-type impurities, and the first active region being connected to the drain region by a third wiring pattern.

6. The semiconductor device of claim 5, wherein the third wiring pattern is connected to the first active region, the drain region, and the gate structure.

7. The semiconductor device of claim 5, wherein the third wiring pattern is isolated from the gate structure.

8. The semiconductor device of claim 5, further comprising:
a second active region disposed in the first well region between the first active region and the second well region in the first direction, the second active region including the first conductivity-type impurities.

9. The semiconductor device of claim 8, wherein an area of the second active region is greater than an area of the first active region.

10. The semiconductor device of claim 5, wherein the first emitter region and the second collector region are disposed between the first active region and the drain region in the first direction.

11. The semiconductor device of claim 10, wherein the first active region includes the first conductivity-type impurities.

12. The semiconductor device of claim 11, wherein the third wiring pattern is disposed in a first wiring layer next to the upper surface of the substrate in a direction perpendicular to the upper surface of the substrate, and wherein a second wiring layer is disposed above the first wiring layer.

13. The semiconductor device of claim 11, further comprising:
a first external resistor configured to connect the gate structure to the source region,
wherein the source region and the second wiring pattern are electrically connected to each other, without an external resistor, by a fourth wiring pattern disposed on the first wiring layer.

14. A semiconductor device, comprising:
a first pad configured to input and output a signal;
a second pad configured to be supplied with a reference voltage;
an NPN transistor including a first collector, a first emitter, and a first base, the first collector connected to the first pad and the first emitter connected to the second pad;
a PNP transistor including a second emitter, a second collector, and a second base, the second emitter connected to the first pad, the second collector connected to the second pad and the first base, and the second base connected to the first collector;
an NMOS transistor including a drain, a source, and a gate, the drain connected to the first collector, the source connected to the second pad, and the gate connected to the source or the drain; and
a first diode including an anode and a cathode, the anode connected to the drain, and the cathode connected to the first collector and the second base.

15. The semiconductor device of claim 14, wherein the NMOS transistor is provided as a second diode to which the gate and the drain are connected.

16. The semiconductor device of claim 14, further comprising:
a first external resistor connected between the source and the gate; and
a second external resistor connected between the source and the second pad.

17. The semiconductor device of claim 14, further comprising:
a first external resistor connected between the source and the gate,
wherein the source and the second pad are electrically connected to each other, without an external resistor, by a wiring pattern.

18. A semiconductor device, comprising:
a first well region and a second well region isolated from each other by a first device isolation film;
an NPN transistor provided by a first collector region and a first emitter region, the first collector region being formed in the first well region and including first conductivity-type impurities, and the first emitter region being formed in the second well region and including the first conductivity-type impurities;
a PNP transistor provided by a second emitter region and a second collector region, the second emitter region being formed in the first well region and including second conductivity-type impurities different from the first conductivity-type impurities, and the second collector region being formed in the second well region and including the second conductivity-type impurities; and
an NMOS transistor including a source region, a drain region, and a gate structure, the source region and the drain region being formed in the second well region and including the first conductivity-type impurities, and the gate structure being disposed between the source region and the drain region,
wherein the source region and the drain region are isolated from each other by the first emitter region and a second device isolation film.

19. The semiconductor device of claim 18,
wherein the first well region and the second well region are disposed in a deep-well region, and
wherein the deep-well region and the first well region include the first conductivity-type impurities, and wherein the second well region includes the second conductivity-type impurities.

20. The semiconductor device of claim 18, wherein an external resistor is connected to at least one of a first region or a second region, the first region being disposed between the source region and the gate structure, and the second region being disposed between the source region and the first emitter region.
